(19) United States
(12) Patent Application Publication
(10) Pub. No.: US 2021/0166990 A1
(43) Pub. Date: Jun. 3, 2021

(54) A FLUIDIC PUMP

(71) Applicant: Alcatel Lucent, Nozay (FR)

(72) Inventors: Nicholas Jeffers, Dublin (IE); Jason Stafford, Dublin (IE); Brian Donnelly, Dublin (IE)

(73) Assignee: Alcatel Lucent, Nozay (FR)

(21) Appl. No.: 16/065,326

(22) PCT Filed: Dec. 16, 2016
(86) PCT No.: PCT/EP2016/081536

§ 371 Date: Jun. 22, 2018

(30) Foreign Application Priority Data
Dec. 23, 2015 (EP) 15307132.9

(51) Int. Cl. H01L 23/38; H01L 23/473; H01L 35/30

(52) U.S. Cl. CPC H01L 23/38; H01L 35/30; H01L 23/473

(57) ABSTRACT

Apparatus and method for pumping fluid to cool a heat source using a thermoelectric cooler to heat a fluid and cause it to flow from a first chamber to through a channel, to a second chamber and vice-versa to make thermal contact with the heat source. During a phase of operation, a control circuit switches off the thermoelectric cooler and measured the electric power generated by the thermoelectric cooler. Depending on the measured value of the power generated by the thermoelectric cooler the flow rate of the fluid is varied to ensure optimal cooling.

The present invention relates to cooling systems and methods of cooling using a fluid.

### BACKGROUND

The recent significant growth in data traffic in telecommunications requires more functionality from future electronic or photonics packages. More functionality implies comparatively higher levels of heat generation. The current thermal solutions employed today do not appear to be capable of scaling sufficiently to meet future network demands. One approach for cooling such components is based on using fluidic pumps.

### SUMMARY

Some embodiments feature an apparatus comprising:
a thermoelectric cooler;
a fluid;
a first chamber and a second chamber connected to one another through a channel;
the thermoelectric cooler being configured to be electrically powered to heat the fluid in the first chamber to cause the fluid to flow through the channel, from the first chamber towards the second chamber and to make thermal contact with a heat source to absorb heat from the heat source;

wherein, the apparatus further comprises a control circuit configured to:
switch off the electric power applied to the thermoelectric cooler;
measure a parameter indicative of electric power generated by the thermoelectric cooler; and
vary a flow rate of the fluid based on the measurement of said parameter obtained from the thermoelectric cooler.

According to some specific embodiments, the control circuit comprises circuitry configured to measure the power generated by the thermoelectric cooler in switched off mode, based on said parameter.

According to some specific embodiments, the control circuit comprises circuitry configured to assess the measurement of said parameter in switched off mode and determine whether the measured parameter is indicative of an optimal operating condition by comparing the measured parameter with a predetermined value or a predetermined range of values.

According to some specific embodiments, the control circuit is configured to vary the flow rate of the fluid by determining a polarity of the measured parameter.

According to some specific embodiments, the control circuit is configured to vary said flow rate to a lower rate for a first polarity of the measured parameter.

According to some specific embodiments, the control circuit is configured to vary said flow rate to a higher rate for a second polarity of the measured parameter opposite to the first polarity.

According to some specific embodiments, the apparatus is configured to:
apply a first polarity of electric power to the thermoelectric cooler to thereby heat the fluid in the first chamber and cause it flow through the channel;
apply a second polarity of electric power opposite to the first polarity to the thermoelectric cooler to thereby heat the fluid in the second chamber and cause it flow through the channel;

wherein a direction of flow of the fluid caused by the first polarity is the same as the direction of flow of the fluid caused by the second polarity.

According to some specific embodiments, the parameter is indicative of electric power is a voltage present between two points, each point located on a respective side of the thermoelectric cooler; or an electric current flowing between said two points.

Some embodiments feature a method comprising:
powering a thermoelectric cooler to heat a fluid in a first chamber to cause the fluid to flow through a channel, from the first chamber towards a second chamber and to make thermal contact with a heat source to absorb heat from the heat source;
switching off the electric power applied to the thermoelectric cooler;
measuring a parameter indicative of electric power generated by the thermoelectric cooler; and
varying a flow rate of the fluid based on the measurement of the parameter obtained from the thermoelectric cooler.

According to some specific embodiments, the method further comprises:
assessing the measurement of said parameter in switched off mode;
comparing the measured parameter with a predetermined value or a predetermined range of values; and
determining whether the measured parameter is indicative of an optimal operating condition.

According to some specific embodiments, the method further comprises determining a polarity of the measured parameter to vary the flow rate of the fluid.

According to some specific embodiments, the method further comprises varying said flow rate to a lower rate for a first polarity of the measured parameter.

According to some specific embodiments, the method further comprises varying said flow rate to a higher rate for a second polarity of the measured parameter opposite to the first polarity.

According to some specific embodiments, the method further comprises:
applying a first polarity of electric power to the thermoelectric cooler to thereby heat the fluid in the first chamber and cause it flow through the channel;
applying a second polarity of electric power opposite to the first polarity to the thermoelectric cooler to thereby heat the fluid in the second chamber and cause it flow through the channel;

wherein a direction of flow of the fluid caused by the first polarity is the same as the direction of flow of the fluid caused by the second polarity.

These and further features and advantages of the present invention are described in more detail, for the purpose of illustration and not limitation, in the following description as well as in the claims with the aid of the accompanying drawings.

### BRIEF DESCRIPTION OF THE DRAWINGS

FIG. 1 is an exemplary schematic representation of a heat transfer assembly comprising a pump according to some embodiments.

FIGS. 2A-2D, collectively FIG. 2, are exemplary schematic representations of various phases of operation of the pump of FIG. 1 under optimal condition.

FIGS. 3A-3D, collectively FIG. 3, are exemplary schematic representations of various phases of operation of the pump of FIG. 1 under a condition where the fluid inlet to the pump has a temperature which is cooler than optimal.

FIGS. 4A-4D, collectively FIG. 4, are exemplary schematic representations of various phases of operation of the pump of FIG. 1 under a condition where the fluid inlet to the pump has a temperature which is hotter than optimal.

### DETAILED DESCRIPTION

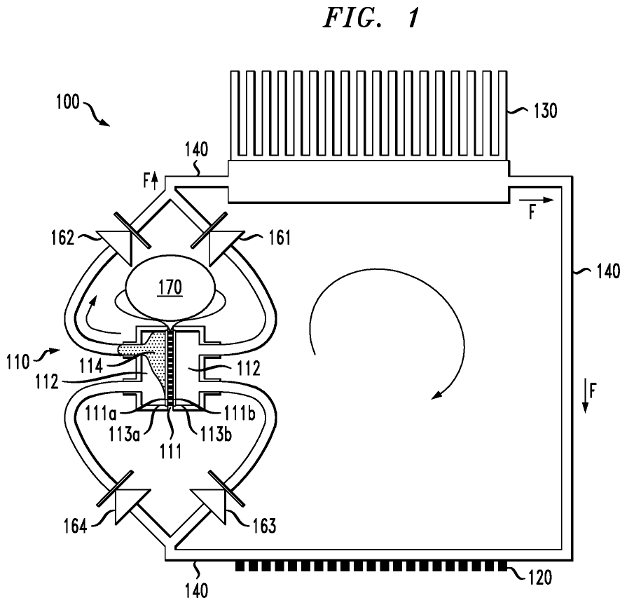

Referring to FIG. 1, there is shown a heat transfer assembly comprising a fluidic pump (herein also referred to as pump) according to some embodiments of the disclosure. Except for the differences mentioned further below, this heat transfer assembly has substantial similarities in structure and operation with a pump described in the European patent application number 14306808.8 filed on 14 Nov. 2014, the content of which is incorporated by reference herein in its entirety.

Referring back to FIG. 1 the heat transfer assembly 100 comprises a pump 110 a heat source 120 such as an optical or electronic component to be cooled and a thermal energy removal mechanism 130 such as a heat sink.

The pump 110 comprises a first chamber 113a and a second chamber 113b.

A working fluid 112 is used for heat transfer operations. The working fluid 112 is provided inside the first chamber 113a and the second chamber 113b and is capable of flowing from one chamber to the other through one or more channels 140.

The channels 140 may be the so-called micro-channels which have at least one cross-sectional dimension below 1 mm in length. Alternatively they may be channels with larger cross-sectional dimensions. Herein, any reference to a channel is to be understood to refer to both such options.

Although in the figure the heat source 120 is shown to be adjacent to the micro-channel 140 and not submerged into the working fluid, the disclosure is not so limited and some embodiments may provide for submerging the heat source 120 inside a region where the working fluid flows, for example inside the cooling chamber 150.

The heat transfer assembly 100 further comprises a TEC 111 provided within the pump 110. A TEC, i.e. Thermoelectric Cooler, is a known solid-state device typically used as heat pump that is capable of pumping heat from one side to the other in response to a supplied voltage. The direction of pumping the heat depends on the polarity of the supplied voltage. If the voltage applied to the TEC is reversed, the direction of the heat pumping effect will also be reversed. Under normal conditions, this heat transfer results in one side of the TEC being above and the other side being below the ambient temperature. By normal condition it is meant to refer to a condition in which the TEC surface temperature is within ±10° C. from the temperature of the working fluid.

A cooling chamber 150 may also be provided to enhance heat transfer from the working fluid to the thermal energy removal mechanism 130.

A plurality of directional valves, 161-164, are provided to ensure a one-directional flow path as will be described below.

In operation, when a voltage is applied to the TEC 111, one side of the TEC (e.g. 111a as shown in the figure) heats up thereby increasing the pressure inside the boundaries of the corresponding chamber 113a where the fluid 112 is contained.

In some embodiments, such as the example shown in FIG. 1, the pump is multi-phase therefore the heating of the one side of the TEC may generate vapor in the form of one or more bubbles 114. In this case the formation and growth of a bubble may be compared to a diaphragm which can extend inside the boundaries of the corresponding chamber, e.g. the left hand side of the pump in FIG. 1, thereby pushing the fluid out of the first chamber 113a.

In some embodiments (not explicitly shown) the pump 100 is not multi-phase therefore the heating of the one side of the TEC may simply cause thermal expansion in the fluid which is sufficient to push the fluid out of the first chamber 113a.

Referring back to FIG. 1, when e.g. side 111a of the TEC 111 is heated, fluid 112 is made to move out of the first chamber 113a (left hand side in the figure). At the same time, side 111b of the TEC 111 is cooled causing the fluid to move into the second chamber 113b (right hand side in the figures).

However while the one-directional valve 162 allows the fluid to flow out of the first chamber 113a, the valve 164 blocks the flow of the fluid in the opposite direction. Therefore the fluid flows in one direction out of valve 162 (e.g. upward in the figures).

As the voltage applied to the TEC 111 is reversed, the opposite side 111b of the TEC is heated up and therefore the fluid is made to move out of the second chamber 113b (right hand side in the figure). At the same time, side 111a of the TEC 111 is cooled and fluid is condensed thus causing the fluid to move into the first chamber 113a (left hand side in the figure).

However while the one-directional valve 161 allows the fluid to flow out of the second chamber 113b, the valve 163 blocks the flow of the fluid in the opposite direction. Therefore the fluid flows in one direction out of valve 161 (e.g. upward in the figure) which is the same direction as in the previous case.

Therefore, for either one of the voltage polarities applied to the TEC 111, the fluid is made to move in one direction out of the pump which is shown by arrows F in FIG. 1.

It is to be noted that when chamber 113a contains hot fluid, it is pressurized thus pushing fluid out (as mentioned above). This effect will also push the one-directional valve 164 to remain closed. At the same time chamber 113b is cooled down and therefore has a reduced pressure therein. This effect will open the one-directional valve 163 and pull the fluid into the chamber 113b.

The directional, or one-way, valves may be active valves (e.g. known check valves with moving parts) or passive valves (e.g. nozzles/diffusers that have no moving parts). Active valves have greater fluidic performance however they have reliability concerns due to said moving part; while passive valves have poorer fluidic performance however they have higher reliability. The choice of the valves may therefore be made in accordance to the practical requirements of each application. The above fluidic pump has many advantages over the known cooling systems. The current generation of these pumps has a small size (e.g. 9 mm×9 mm×3 mm which means nearly 10 times smaller than conventional pumps) and can achieve flow rates of up to 20 ml/min and maximum pressures of up to 20 kPa which may be considered as very good performance factors. Furthermore, as these pumps may be based on solid state technologies with no moving parts they may likely be very reliable.

However, the inventors have recognized that the performance of such fluidic pumps may be affected by ambient temperature variations. For example, with certain fluidic pumps a 10° C. ambient temperature change may negatively affect such performance and thereby deteriorate the cooling efficiency.

By “ambient temperature” it is meant to refer to the temperature surrounding the pump. Although it may not always be the case, but typically such surroundings may be inside a cabinet or any similar housing in which the pumps operates.

It is therefore desired to provide a control mechanism to keep the pump operating optimally and, as much as possible, independently from room temperature.

The present disclosure addresses the above considerations. Accordingly a novel cooling architecture is proposed comprising a fluidic pump as described above and an additional mechanism to control the operation of the pump to ensure optimal performance as described in further detail below.

The present disclosure takes advantage of the fact that power is generated from a Thermoelectric Cooler (TEC) when a temperature difference exists between two sides of the same. This feature of a TEC is used in order to effectively monitor the temperature of the fluid entering the pump. The temperature is used as a feedback in order to control the pump flow rate.

Basically there is fundamentally little difference between a TEC and a Thermoelectric Generator (TEG). The main difference between these two elements is how they are deployed, i.e. typically the TEC is used for cooling purposes while the TEG is used to generate power. In other words, a TEC generates a temperature difference at its sides in response to receiving an electrical excitation at respective points on each side (e.g. using electrodes) and a TEG generates electricity at respective points on each side in response to experiencing a temperature difference between said sides. Thus the same device could be used for one or the other purpose depending on how it is deployed. In the forgoing reference will be made to TEC, however it is to be understood that at certain phases of operation the TEC may be operating as a TEG as mentioned above.

Referring back to the fluidic pump 100 of FIG. 1, it may therefore be understood that if there is a difference in temperature between side 111a and 111b, and the electric voltage is disconnected from the TEC 111, a voltage difference will be present between the sides 111a and 111b which can be measured by known means.

In order to ensure optimum operation, little difference in temperature should exist between the hot and the cold side of the TEC in the fluidic pump, because the pump is constantly cycling between expanding and condensing the working fluid as described above. During this process the temperature remains fixed because the cooling and heating energy from the TEC is consumed by the latent heat of expansion and condensation.

Therefore under satisfactory (or optimal) conditions, where the temperature difference between the two side of the TEC is low, minimal power is generated if the electric power to the TEC is switched off for a fraction of a second and the power generated is measured. Conversely, higher temperature differences between the sides of the TEC would result in higher power generated. The voltage generated by the TEC 111 is directly proportional to the power generated thus only voltage may be monitored. Current is also proportional to the power generated and the control circuit could likewise be configured for to measure current.

Referring back to FIG. 1, pump 100 a control circuit 170 is shown. The control circuit may include circuitry for measuring voltage. However, as mentioned above the current may be measure instead.

Due to the possibility of variation in the temperature of the two sides of the TEC, either a positive voltage or a negative voltage may be generated. If a positive voltage is generated then it may be determined that the inlet fluid temperature is too cool possibly caused by a reduction ambient temperature. Likewise, if a negative voltage is generated then it may be determined that the fluid entering into the pump is too hot possibly caused by an increase ambient temperature.

The control circuit 170 may be configured to take actions to increase or decrease the flow rate in the pump thus controlling the temperature at which the fluid leaves the cooling chamber and consequently the fluid temperature that is recycled back into the pump. This mechanism can therefore ensure that the fluid inlet temperature into the pump is maintained constant, or at least within an acceptable fluctuation range, regardless of ambient temperature fluctuations.

For example, if the pump fluid 112 is configured to change phase in an ambient temperature of 55° C. (which is the standard required by Network Equipment Building Systems, i.e. NEBS) and the actual ambient temperature fluctuates between 40° C. (winter) and 55° C. (summer) then it will be more difficult for the TEC 111 in the pump to heat the fluid to cause efficient thermal expansion therein in such a cooler ambient because a substantial amount of thermal energy from the TEC 111 will be consumed by sensible heating (sensible heating results in an increase in fluid temperature without a change in phase). Therefore the control circuit may operate to maintain constant, or with minimal fluctuation, the fluid inlet temperature into the pump, regardless of the external ambient temperature. This may be achieved by increasing and decreasing the flow rate in the loop which in turn increases and decreases the time that the fluid spends in contact with the heat source 120.

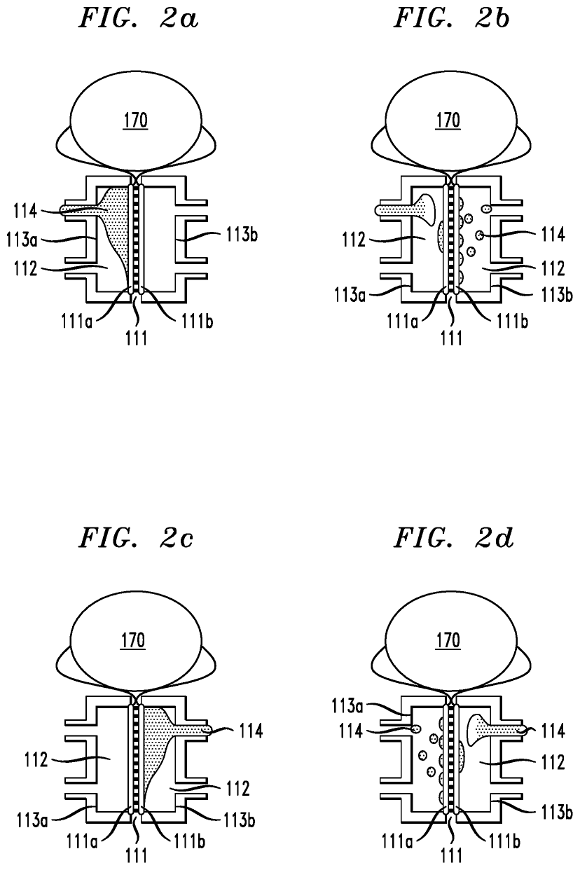

This operation is described below with reference to FIGS. 2, 3 and 4. In these figures like elements have been provided with like reference numerals as those of FIG. 1.

FIGS. 2a-2d show various phases of an optimal operation of an exemplary pomp 100 as described with reference to FIG. 1.

FIG. 2a shows an initial phase, say at time zero, in which side 111a of the TEC 111 heats the fluid 112 thereby causing the fluid to flow out of chamber 113a, e.g. by generating bubbles 114 as shown in the figure. Side 111b of the TEC 111 is cooler and thus fluid flows inside chamber 113b. It is assumed that the inlet temperature of the fluid in chamber 113b is 54.4° C.

Herein, the term inlet fluid temperature is meant to refer to the temperature of the fluid entering a chamber which is being cooled and outlet fluid temperature is meant to refer to the temperature of the fluid leaving a chamber which is being heated.

FIG. 2b shows a second phase, say at 0.5 second from the first phase, in which the polarity of the electric voltage (or current) applied to the TEC is reversed. Therefore, side 111b of the TEC 111 heats the fluid 112 which would eventually cause thermal expansion in the fluid (with or without bubbles 114). Side 111a of the TEC 111 cools down.

At a certain point during this second phase, for example at the start of the fluid phase change, the electric power applied to the TEC 111 is switched off and a voltage measurement is performed by the control circuit 170. The measurement may take a relatively short time for example 0.05 sec. It is again assumed that the inlet temperature of the fluid in chamber 113a is 54.4° C. and the outlet temperature of the fluid in chamber 111b is 55° C.

The control circuit then determines whether the measured voltage (which is proportional to the electric power) is indicative of an optimal operating condition by comparing the measured voltage (or the related power) with a predetermined value or a predetermined range of values. For example, the predetermined value may be 2V. Therefore if the measured voltage is any value having a magnitude (i.e. either positive or negative) lower than this predetermined value it is determined that the optimal conditions of operation are present. Otherwise, it is determined that optimal conditions are not present.

In the present example, as the temperature difference between the fluids in the two chambers is relatively low, i.e. only 0.5° C., the voltage measured at output terminals of the TEC would also be low, for example lower than 1V. This low voltage is therefore indicative of optimal operation of the pump 100.

Although in the examples provided herein it is mentioned that the control circuit measures voltage, the disclosure is not so limited and the control circuit may likewise be configured to measure a current flowing through the two measurement points. As the voltage and the current are both proportional to the electric power generated by the TEC in the switched off mode, they may be collectively referred to as parameters indicative of electric power.

FIGS. 2c and 2d show subsequent phases, say at 1 second and 1.5 seconds after the first phase respectively. As can be seen in FIG. 2c, the operation is similar to that of the initial phase of FIG. 2a but with an opposite polarity. Therefore fluid is caused to flow out of chamber 113b. FIG. 2d, shows once more a reversal of the polarity of the voltage applied to the TEC with consequences similar to those of FIG. 2b but with an opposite polarity. At this stage it is not needed to turn the power off for another measurement; however this possibility is not excluded. Similar temperature differences as those mentioned with reference to FIGS. 2a and 2b may also be considered in the fluid of the two chambers for these phases.

However, if the ambient temperature drops (e.g. to 40° C.), it will have the effect of cooling the fluid 112 more at the cooling chamber 150 (FIG. 1). Therefore the inlet fluid temperature entering the pump 100 becomes too cool and requires a substantial amount of sensible heating before the fluid expands. This hampers the performance of the pump and in extreme circumstances could cause the pump to stop pumping, leading to component failure.

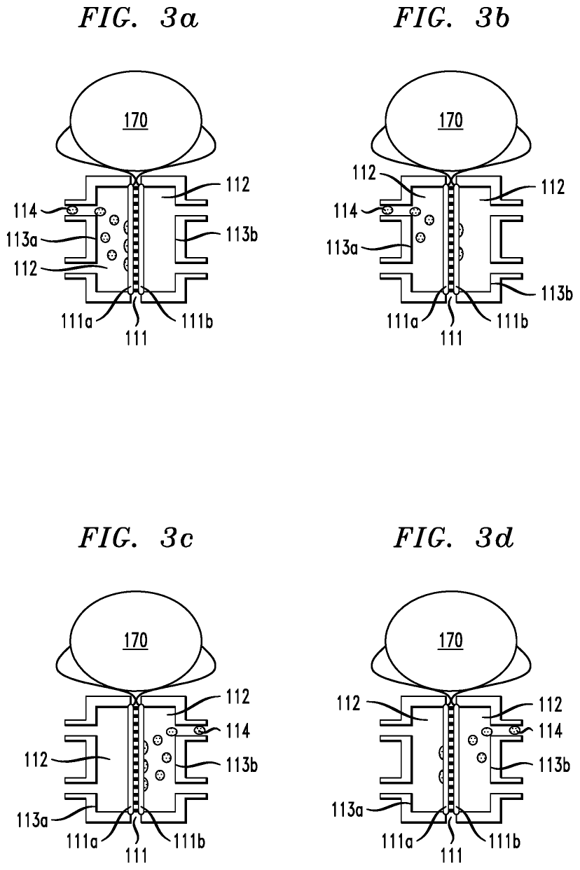

FIGS. 3a-3d show various phases of operation of the exemplary pump 100 of FIG. 1 under conditions in which the inlet fluid temperature is too cool. In the context of the present disclosure when the temperature of the inlet fluid is 5° C. or more lower than the temperature of the outlet fluid it may be considered that the inlet temperature is too cool.

FIG. 3a shows an initial phase, say at time zero, in which side 111a of the TEC 111 heats the fluid 112, thereby causing the fluid to heat up and thermally expand (with or without generating bubbles 114). However the inlet flow temperature within side 111b of the TEC 111 is too cool, in this example 45° C. Therefore, the operation of the pump is not optimal.

FIG. 3b shows a second phase, say at 0.5 second from the first phase, in which the polarity of the electric voltage (or current) applied to the TEC is reversed. Therefore, side 111b of the TEC 111 heats the fluid 112 while side 111a of the TEC 111 cools down. At a certain point during this second phase, for example at the start of the phase, the electric power applied to the TEC 111 is switched off and a voltage measurement is performed by the control circuit 170. Similar to the description of FIG. 2b, here also the measurement may take a relatively short time for example 0.05 sec. In this case however, the inlet temperature of the fluid in chamber 113a is too cool, e.g. 44° C. as compared to the outlet temperature of the fluid in chamber 111b e.g. 54° C.

As the temperature difference between the fluids in the two chambers is relatively high, i.e. 10° C., the voltage measured at output terminals of the TEC would also be high. Therefore the voltage generated is greater than the voltage at optimal conditions. Assuming that a positive voltage is generated, the control circuit 170 may include preprogrammed circuitry configured to determine that such positive voltage is indicative of a drop in the inlet fluid temperature. The control circuit 170 may further be programmed to take action to slow down the flow rate in the pump. For example the control circuit may take action to increase the off time of the TEC 111 to more than 0.05 second to thereby reduce the flow rate of the fluid 112 through the pump 100. This causes the fluid to stay a longer period of time in thermal contact (directly or indirectly) with the heat source 120 resulting in an increase in the inlet fluid temperature, thus returning the pump 100 to the optimal state of operation as described with reference to FIG. 2.

FIGS. 3c and 3d show subsequent phases, say at 1 second and 1.5 second after the first phase respectively. As can be seen in FIG. 3c, the operation is similar to that of the initial phase of FIG. 3a but with an opposite polarity. Therefore fluid is heated in chamber 113b. FIG. 3d, shows once more a reversal of the polarity of the voltage applied to the TEC with consequences similar to those of FIG. 3b but with an opposite polarity. At this stage it is not needed to turn the power off for another measurement; however this possibility is not excluded.

Alternatively the inlet fluid temperature may become too hot due to an increase in the ambient temperature.

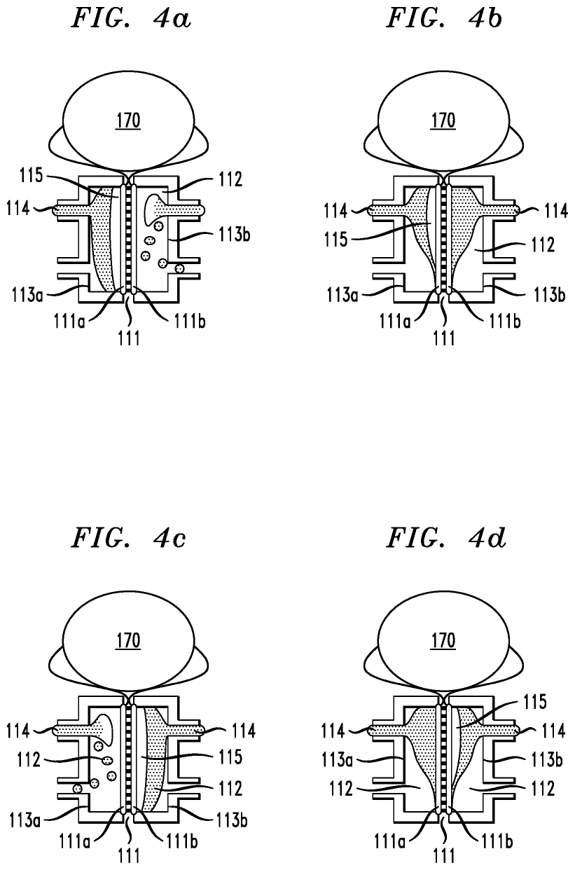

FIGS. 4a-4d show various phases of operation of the exemplary pump 100 of FIG. 1 under conditions in which the inlet fluid temperature is too hot.

In the context of the present disclosure when the temperature of the inlet fluid is 10° C. or more higher than the temperature of the outlet fluid it may be considered that the inlet fluid temperature is too hot.

FIG. 4a shows an initial phase, say at time zero, in which side 111a of the TEC 111 heats the fluid 112, thereby causing the fluid to heat up and thermally expand. However the inlet flow temperature within side 111b of the TEC 111 is too hot, in this example above 55° C. Therefore, the operation of the pump is not optimal. Furthermore, as the temperature of the fluid in chamber 113a become very hot (due to the combined effect of the high ambient temperature and the TEC heating action), a dry out bubble 115 may be formed which may hamper an efficient exchange of heat between the side 111a and the fluid in chamber 113a.

FIG. 4b shows a second phase, say at 0.5 second from the first phase, in which the polarity of the electric voltage (or current) applied to the TEC is changed. Therefore, side 111b of the TEC 111 heats the fluid 112 while side 111a of the TEC 111 cools down. However the temperature at the inlet side, in this case chamber 113a, is still high. Furthermore, the generation of the dry out bubble 115 impedes an efficient heat transfer between the fluid and the cooling side 111a thereby hampering the reduction of temperature of the fluid in this chamber. This is because when a dry out occurs on the TEC surface during the heating phase on that surface the temperature rapidly increases far beyond the phase change temperature of the fluid. Therefore when the cooling cycle of that same surface begins the TEC is required to cool such excessive heat therefore hampering its performance.

At a certain point during this second phase, for example at the start of the phase, the electric power applied to the TEC 111 is switched off and a voltage measurement is performed by the control circuit 170. The measurement may take a relatively short time for example 0.05 sec. In this case however, the inlet temperature of the fluid in chamber 113a is too high, e.g. 65° C. as compared to the outlet temperature of the fluid in chamber 111b e.g. 55° C.

As the temperature difference between the fluids in the two chambers is relatively high, i.e. 10° C., the voltage measured at output terminals of the TEC would also be high. Therefore the voltage generated is greater than the voltage in an optimal condition. Assuming that a negative voltage is generated, the control circuit 170 may be preprogrammed to determine that such negative voltage is indicative of an increase in the inlet fluid temperature. The control circuit 170 may further be programmed to take action to speed up the flow rate in the pump. For example the control circuit 170 may take action to decrease the off time of the TEC 111 to lower than 0.05 second to thereby increase the flow rate of the fluid 112 through the pump 100. This causes the fluid to stay a shorter period of time in contact (directly or indirectly) with the heat source 120 resulting in the inlet fluid temperature to decrease, thus returning the pump 100 to the optimal state of operation as described with reference to FIG. 2.

FIGS. 4c and 4d show subsequent phases, say at 1 second and 1.5 second after the first phase respectively. As can be seen in FIG. 4c, the operation is similar to that of the initial phase of FIG. 4a but with an opposite polarity. Therefore fluid is heated in chamber 113b. FIG. 4d, shows once more a reversal of the polarity of the voltage applied to the TEC with consequences similar to those of FIG. 4b but with an opposite polarity.

In this manner, it becomes possible to deploy a fluidic pump in an environment with a fluctuating ambient temperature without compromising the performance of the pump. The proposed solution allows for designing equipment in compliance with the stringent requirements of the NEBS standard which at times become difficult to achieve. The control circuit can be used to ensure that the pump is optimized to operate under harsh conditions.

The control circuit can be any of hardware devices, software modules or combination of hardware devices and software modules known in the related art. The control circuit may include circuitry for measuring voltage and/or current and for assessing the measurements and taking appropriate actions as described above. Such circuitry may include known means such as an Application Specific Integrated Circuit (ASIC), a Field Programmable Gate Array (FPGA) and/or a microprocessor, and in a preferred embodiment through or together with a suitable software program may be used.

Further it is to be noted that the list of structures corresponding to the claimed means is not exhaustive and that one skilled in the art understands that equivalent structures can be substituted for the recited structure without departing from the scope of the disclosure.

It is also to be noted that the order of the steps of the method as described and recited in the corresponding claims is not limited to the order as presented and described and may vary without departing from the scope of the disclosure. It should be appreciated by those skilled in the art that any block diagrams herein represent conceptual views of illustrative circuitry embodying the principles of the disclosure.

1. An apparatus comprising:
a thermoelectric cooler;
a fluid;
a first chamber and a second chamber connected to one another through a channel;
the thermoelectric cooler being configured to be electrically powered to heat the fluid in the first chamber to cause the fluid to flow through the channel, from the first chamber towards the second chamber and to make thermal contact with a heat source to absorb heat from the heat source;
wherein, the apparatus further comprises a control circuit configured to:
switch off the electric power applied to the thermoelectric cooler;
measure a parameter indicative of electric power generated by the thermoelectric cooler; and
vary a flow rate of the fluid based on the measurement of said parameter obtained from the thermoelectric cooler.

2. The apparatus of claim 1, wherein, the control circuit comprises circuitry configured to measure the power generated by the thermoelectric cooler in switched off mode, based on said parameter.

3. The apparatus of claim 1, wherein the control circuit comprises circuitry configured to assess the measurement of said parameter in switched off mode and determine whether the measured parameter is indicative of an optimal operating condition by comparing the measured parameter with a predetermined value or a predetermined range of values.

4. The apparatus of claim 1, wherein the control circuit is configured to vary the flow rate of the fluid by determining a polarity of the measured parameter.

5. The apparatus of claim 4, wherein the control circuit is configured to vary said flow rate to a lower rate for a first polarity of the measured parameter.

6. The apparatus of claim 5, wherein the control circuit is configured to vary said flow rate to a higher rate for a second polarity of the measured parameter opposite to the first polarity.

7. The apparatus of claim 1, wherein the apparatus is configured to:
apply a first polarity of electric power to the thermoelectric cooler to thereby heat the fluid in the first chamber and cause it flow through the channel;
apply a second polarity of electric power opposite to the first polarity to the thermoelectric cooler to thereby heat the fluid in the second chamber and cause it flow through the channel;
wherein a direction of flow of the fluid caused by the first polarity is the same as the direction of flow of the fluid caused by the second polarity.

8. The apparatus of claim 1, wherein the parameter indicative of electric power is a voltage present between two points, each point located on a respective side of the thermoelectric cooler; or an electric current flowing between said two points.

9. A method comprising:
powering a thermoelectric cooler to heat a fluid in a first chamber to cause the fluid to flow through a channel, from the first chamber towards a second chamber and to make thermal contact with a heat source to absorb heat from the heat source;
switching off the electric power applied to the thermoelectric cooler;
measuring a parameter indicative of electric power generated by the thermoelectric cooler; and
varying a flow rate of the fluid based on the measurement of the parameter obtained from the thermoelectric cooler.

10. The method of claim 9 further comprising:
assessing the measurement of said parameter in switched off mode;
comparing the measured parameter with a predetermined value or a predetermined range of values; and
determining whether the measured parameter is indicative of an optimal operating condition.

11. The method of claim 9, further comprising determining a polarity of the measured parameter to vary the flow rate of the fluid.

12. The method of claim 11, comprising varying said flow rate to a lower rate for a first polarity of the measured parameter.

13. The method of claim 12, comprising varying said flow rate to a higher rate for a second polarity of the measured parameter opposite to the first polarity.

14. The method of claim 9, comprising:
applying a first polarity of electric power to the thermoelectric cooler to thereby heat the fluid in the first chamber and cause it flow through the channel;
applying a second polarity of electric power opposite to the first polarity to the thermoelectric cooler to thereby heat the fluid in the second chamber and cause it flow through the channel;
wherein a direction of flow of the fluid caused by the first polarity is the same as the direction of flow of the fluid caused by the second polarity.

15. The method of claim 9, wherein the parameter indicative of electric power is a voltage present between two points, each point located on a respective side of the thermoelectric cooler; or an electric current flowing between said two points.
